(19) United States
(12) Patent Application Publication
(10) Pub. No.: US 2025/0353121 A1
(43) Pub. Date: Nov. 20, 2025

(54) Substrate carrier, substrate carrier holding device, vacuum arrangement, use and method

(71) Applicant: VON ARDENNE Asset GmbH & Co. KG, Dresden (DE)

(72) Inventors: Stephan Aulhorn, Radebeul (DE); Torsten Winkler, Radeberg (DE); Michael Hentschel, Dresden (DE); Ruben Grosche, Dresden (DE)

(21) Appl. No.: 19/206,164

(22) Filed: May 13, 2025

(30) Foreign Application Priority Data
May 14, 2024 (DE) 10 2024 113 390.2

(51) Int. Cl. B23K 37/04; B23K 26/352; B23K 37/047

(52) U.S. Cl. CPC B23K 37/0443; B23K 26/3584; B23K 37/047

(57) ABSTRACT

A substrate carrier segment may include a carrier frame, a substrate holding device for holding a substrate, which is at least partially integrated into the carrier frame or mounted thereon; a mounting device adjacent to the carrier frame for mounting the substrate carrier segment, towards which the carrier frame tapers; and two form-fitting contours, which are configured complementary to one another and between which an outer side of the carrier frame opposite the mounting device is arranged.

### CROSS-REFERENCE TO RELATED APPLICATION

This Patent application claims priority from German Patent Application No. 10 2024 113 390.2 filed on May 14, 2024 according to 35 U.S.C. § 119, the entire disclosure of which is incorporated herein by reference and for all purposes.

### TECHNICAL FIELD

Various embodiments relate to a substrate carrier, a substrate carrier holding device, a vacuum arrangement, a usage and a method.

### BACKGROUND

In general, a substrate may be treated (processed) in a vacuum, e.g. coated, so that the chemical and/or physical properties of the substrate may be changed. Various coating processes may be used to coat a substrate, of which physical vapor deposition (PVD) is an established representative. For example, a vacuum coating system may be used to deposit one or more layers on one or more substrates by chemical and/or physical vapor deposition. Such a vacuum coating system can, for example, be of the so-called rotary table type or of the so-called continuous flow type.

The turntable system has a plate-shaped substrate carrier (also known as a turntable), which carries several substrates and is set in a rotary motion so that the substrates are transported along a circular transport path. The turntable system is a compact alternative to the continuous system, in which the substrate is transported along a straight transport path through the entire vacuum coating system, which requires a lot of installation space

### SUMMARY

For various applications, there are high demands on the result of the coating process, which may be carried out in such a turntable system. Here various design and process parameters interact, which may influence the result of the coating process.

According to various embodiments, a substrate carrier, a substrate carrier holding device, a vacuum arrangement, a use and a method are provided, which make it easier to meet high requirements for the result of the coating process (also referred to as process requirements). For example, it is facilitated to reduce the variance of the substrate position, for example relative to a coating device.

It was illustratively recognized that the spatial position (i.e. location and/or orientation) of the substrate (also referred to as substrate position), in which the substrate is transported in the vacuum chamber, becomes increasingly important as a process parameter of the coating process with increasing process requirements. Among other things, this position influences the distance of the substrate from the coating device and thus how the substrate is exposed to the coating material.

In this context, it was recognized that this substrate position is a function of the precession with which the substrate carrier, by which the substrate is carried during transport, may be mounted and configured. However, conventional substrate carriers offer little scope for improving this precision

For example, a substrate carrier often has several segments (also referred to as a substrate carrier segment), which may be individually loaded and mounted with substrates (then also referred to as a multi-part substrate carrier). The assembled substrate carrier segments then form a ring-shaped structure, for example, in the center of which the axis of rotation of the substrate carrier is arranged, of which each substrate carrier segment may hold one or more than one substrate.

In light thereof, various embodiments are provided which facilitate the provision (e.g. manufacture and/or assembly) of a precisely configured substrate carrier. For example, the precision with which each substrate carrier segment is assembled is improved. For example, the precision with which each substrate carrier segment is manufactured is improved. This reduces variances, e.g. manufacturing deviations and/or assembly deviations, which have a disruptive effect on the substrate position.

In the following, various examples are described which relate to the above described and illustrated in the figures.

Example 1 is configured according to one of the appended claims.

Example 2 is a substrate carrier segment (preferably configured according to example 1), comprising a carrier frame; a substrate holding device for holding a substrate, which is at least partially integrated into the carrier frame or mounted thereon; a mounting device adjacent to the carrier frame for mounting the substrate carrier segment, towards which the carrier frame tapers; two form-fit contours (also referred to as support contours), which are configured complementary to one another and between which an outer side of the carrier frame opposite the mounting device is arranged.

Example 3 is configured in accordance with one of examples 1 to 2, wherein the support frame has two opposing end faces, which are configured in relation to each other (e.g. at an angle to each other) in such a way that the support frame tapers towards the mounting device.

Example 4 is configured in accordance with one of examples 1 to 3, with each of the form-fit contours being provided on one of the end faces.

Example 5 is a substrate carrier segment (preferably according to one of the examples 1 to 4), including: two mutually opposite end faces which are arranged relative to one another (e.g. having edges at an angle to one another) in such a way that the substrate carrier segment tapers towards an axis of rotation; a mounting device, facing the axis of rotation, for mounting the substrate carrier segment. (e.g. having edges at an angle to one another) such that the substrate carrier segment tapers towards an axis of rotation; a mounting device facing the axis of rotation for mounting the substrate carrier segment; a substrate holding device which is configured to hold a substrate and which is arranged between the two end faces; two form-fitting contours which are arranged complementarily to one another and of which each form-fitting contour is provided on one of the end faces.

Example 6 is configured according to one of the examples 1 to 5, wherein the two positive locking contours include a first positive locking contour, which is preferably disposed on a first end face of the two end faces and/or includes a projection; wherein the two positive locking contours include a second positive locking contour, which is preferably disposed on a second end face of the two end faces and/or includes a recess complementary to the projection.

Example 7 is configured according to one of examples 1 to 6, wherein an integer times an angle at which the two end faces extend towards each other and/or at which the support frame tapers is approximately 360 degrees.

Example 8 is configured according to one of the examples 1 to 7, whereby the two form-fit contours (e.g. end faces by their form-fit contour) are configured to interlock.

Example 9 is configured according to one of the examples 1 to 8, whereby the two form-fit contours (e.g. end faces by their form-fit contour) are configured for centering.

Example 10 is configured according to one of the examples 1 to 9, whereby the positive locking contours are configured to implement a mortise and tenon joint.

Example 11 is configured according to one of the examples 1 to 10, wherein one or more than one of the form-fit contours is wedge-shaped, e.g., at least sectionally.

Example 12 is configured according to one of examples 1 to 11, wherein a first form-fit contour of the two form-fit contours is provided by a projection which is preferably (at least sectionally) wedge-shaped and/or step-shaped, and wherein the first form-fit contour is preferably provided by a peg-shaped plug-in device which continues a wedge-shaped section of the projection and/or faces away from the second form-fit contour of the two form-fit contours.

Example 13 is configured according to one of examples 1 to 12, wherein the substrate holding device is configured to hold two substrates on top of each other, e.g. at a distance from each other.

Example 14 is configured according to one of examples 1 to 13, wherein the substrate holding device is configured to positively receive one or more than one substrate.

Example 15 is configured according to any one of examples 1 to 14, further comprising: a machining pattern according to which the substrate carrier segment (e.g. a surface thereof and/or an edge thereof) is machined (e.g. separated and/or roughened), wherein the machining pattern is symmetrical, preferably to an axis (e.g. axis of symmetry of the substrate carrier) extending away from the mounting device.

Example 16 is configured according to any one of examples 1 to 15, further comprising a rolling direction which is parallel or transverse to an axis of symmetry of the substrate carrier segment and/or which is parallel or transverse to an axis (e.g. axis of symmetry of the substrate carrier) extending away from the mounting device.

Example 17 is configured according to one of examples 1 to 16, further comprising: the outer side facing away from the mounting device having one or more than one (e.g. aisle-shaped) recess (also referred to as a coupling recess or handler pocket) on the outer side (e.g. towards the mounting device and/or extending into the frame), of which each recess is preferably: angled in a direction towards one of the two positive locking contours (or at least end faces); has a section tapering towards the mounting device; and/or is bounded by a meandering positive locking contour.

Example 18 is a substrate carrier comprising a plurality of substrate carrier segments, each substrate carrier segment being configured according to one of examples 1 to 17.

Example 19 is a substrate carrier holding device, comprising: an axis of rotation, a plurality of mounting sockets (also referred to as mounting device of the substrate carrier holding device) configured according to a pattern (symmetrical to the axis of rotation) around the axis of rotation, each mounting socket comprising: a (e.g. movably, e.g., rotatably, supported) receiving device for receiving a substrate carrier segment, preferably configured according to one of examples 1 to 17; a (e.g., mechanical) first manipulation member (also referred to as alignment member) arranged (preferably in response to being actuated) for changing an angle (also referred to as alignment angle) between the axis of rotation and the receiving device; an optional locking device configured to selectively lock or release (preferably in response to being actuated) the changing of the angle; an optional pivot joint (e.g., including one or more than one hinge) by which the receiving device is movably supported.

Example 20 is configured according to example 19, further comprising: a bearing device (also referred to as a pedestal bearing) by which the receiving device is movably (e.g., rotatably) mounted relative to the axis of rotation; the pedestal bearing preferably comprising a pivot bearing (e.g., rotational bearing).

Example 21 is configured according to example 19 or 20, wherein the first manipulation member is configured to transmit a torque to the receiving device for changing the angle and/or comprises a gear (e.g. provided by a thread) for transmitting the torque.

Example 22 is configured according to example 19 or 21, wherein the holding device has two clamping jaws (e.g., chuck jaws) which are mounted movable relative to one another and between which a receiving gap is formed and/or is held by the first manipulation member.

Example 23 is configured according to example 22, wherein the holding device has a spring for providing a restoring force which is mediated between the clamping jaws, preferably forcing them apart.

Example 24 is configured according to example 22 or 23, wherein the pick-up device comprises one or more than one protrusion for limiting a movement path when picking up the substrate carrier segment, wherein preferably the second (e.g., mechanical) manipulation member is arranged at least partially between two protrusions of the pick-up device and/or of which preferably each protrusion comprises a rotatably mounted ring.

Example 25 is configured according to one of the examples 22 to 24, wherein the mounting device has a second manipulation member for transmitting a force into the receiving area and/or for mediating the force between the clamping jaws, preferably for clamping the mounting device.

Example 26 is configured according to example 25, whereby the second manipulation member has a gear (e.g. provided by a thread) which couples the clamping jaws together.

Example 27 is a vacuum arrangement comprising: a vacuum chamber, a substrate carrier holding device according to any one of examples 23 to 26, which is arranged in the vacuum chamber.

Example 28 is configured according to example 27, further comprising a coating device which is configured to emit a coating material to which the substrate carrier holding device is preferably exposed.

Example 29 is configured according to example 27 or 28, several substrate carrier segments, preferably configured according to one of examples 1 to example 17, are held by the substrate carrier holding device.

Example 30 is a use of a thermal process (e.g. ablation process and/or irradiation process) for forming (e.g. manufacturing) a substrate carrier segment (preferably configured according to one of examples 1 to example 17), which is carried out according to a process pattern that is symmetrical to an axis of symmetry of the substrate carrier segment and/or to an angle at which two opposite end faces of the substrate carrier segment extend with respect to each other.

Example 31 is configured according to example 30, whereby the thermal process is carried out by a laser (then also referred to as laser ablation process).

Example 32 is configured according to one of examples 30 or 31, wherein the process pattern implements several pairs of regions (also referred to as irradiation regions), e.g. of the substrate carrier segment, wherein the irradiation regions of a pair are symmetrical to the symmetry axis and/or to the angle and are exposed to the process (e.g. ablation process and/or irradiation process) immediately one after the other.

Example 33 is configured according to one of the examples 30 to 32, wherein the process pattern is symmetrical to a rolling direction and/or a rolling edge of the substrate carrier segment or at least one pre-product (e.g. a plate, e.g. metal plate) from which the substrate carrier segment is formed. The pre-product may include or be formed from bar stock (also referred to as blank, slug or billet).

Example 34 is configured according to one of the examples 30 to 33, wherein the process pattern is configured such that a tensioning of the substrate carrier segment caused by the ablation process is symmetrical to the angle and/or the symmetry axis.

Example 35 is configured according to one of examples 30 to 34, wherein the process (e.g. ablation process and/or irradiation process) comprises a roughening laser.

Example 36 is configured according to one of the examples 30 to 35, wherein the process (e.g. ablation process and/or irradiation process) comprises laser cutting (also referred to as laser cutting process).

Example 37 is a method (preferably according to any one of examples 1 to 36), comprising: controlling a thermal process (e.g. ablation process and/or irradiation process) according to a process pattern; forming a substrate carrier segment (preferably configured according to any one of examples 1 to example 17) by the thermal process (e.g., ablation process and/or irradiation process), wherein the process pattern is symmetrical to an angle at which two opposite end faces of the substrate carrier segment extend relative to each other and/or to an axis of symmetry of the substrate carrier segment.

Example 38 is configured according to one of the examples 1 to 37), wherein the mounting device is plate-shaped and/or is configured for insertion into a receiving gap.

Example 39 is configured according to one of examples 1 to 38), wherein the mounting device includes one or more than one recess (also referred to as mounting recesses) which is open in a direction (e.g. radial direction) away from the substrate holding device.

Example 40 is configured according to one of the examples 1 to 39), whereby the support frame is monolithically connected to the mounting device and/or the two form-fitting contours.

Example 41 is configured according to one of examples 1 to 40), wherein a first of the two form-fit contours is provided by a centering wedge and a second of the two form-fit contours is provided by a centering funnel complementary to the centering wedge.

Example 42 is configured according to one of examples 1 to 41), wherein a first of the two form-fit contours is provided by a pin and a second of the two form-fit contours is provided by a groove complementary to the pin.

Example 43 is configured according to one of examples 1 to 42, the substrate carrier segment further comprising an axis of symmetry to which a processing pattern according to which the substrate carrier segment is roughened is symmetrical.

Example 44 is configured according to one of examples 1 to 43, the substrate carrier segment further comprising an axis of symmetry to which a rolling direction of the substrate carrier segment extends transversely.

Example 45 is configured according to one of examples 1 to 44, wherein the axis of symmetry is a bisector of an angle at which two opposite end faces of the substrate carrier segment extend relative to one another.

Example 46 is configured according to one of examples 1 to 45, wherein two opposite end faces of the substrate carrier segment coincide at an angle at which they extend with respect to the axis of symmetry of the substrate carrier segment.

### BRIEF DESCRIPTION OF THE DRAWINGS

FIGS. 1A and 2A each show a substrate carrier segment according to various embodiments in a schematic side view or cross-sectional view;

FIG. 1B shows a substrate carrier according to various embodiments in a schematic side view or cross-sectional view;

FIGS. 2B and 3A each show a transport device according to different embodiments in different schematic views;

FIG. 3B shows a schematic perspective view of a mounting device according to various embodiments;

FIG. 4A shows a schematic perspective view of a mounting socket according to various embodiments;

FIG. 4B shows a transport device according to various embodiments in a schematic side view or cross-sectional view;

FIGS. 5A and 5B each show a substrate carrier segment according to various embodiments in a schematic side view or cross-sectional view;

FIG. 5C shows a transport device according to various embodiments in a schematic side view or cross-sectional view;

FIGS. 6A and 6B each show a substrate carrier segment according to various embodiments in a schematic side view or cross-sectional view;

FIGS. 7A and 7B each show a process pattern according to different embodiments in a schematic diagram;

FIGS. 8A and 8B each show a process pattern according to different embodiments in a schematic diagram; and

FIGS. 9A and 9B each show a vacuum arrangement according to different embodiments in a schematic side view or cross-sectional view.

### DETAILED DESCRIPTION

In the following detailed description, reference is made to the accompanying drawings which form part thereof and in which specific embodiments in which the invention may be practiced are shown by way of illustration. In this regard, directional terminology such as “top”, “bottom”, “front”, “rear”, “front”, “rear”, etc. is used with reference to the orientation of the figure(s) described. Since components of embodiments may be positioned in a number of different orientations, the directional terminology is for illustrative purposes and is not limiting in any way. It is understood that other embodiments may be used and structural or logical changes may be made without departing from the scope of protection of the present invention. It is to be understood that the features of the various exemplary embodiments described herein may be combined with each other, unless specifically indicated otherwise. The following detailed description is therefore not to be construed in a limiting sense, and the scope of protection of the present invention is defined by the appended claims.

In the context of this description, the terms “connected”, “connected” and “coupled” are used to describe both a direct and an indirect connection (e.g. ohmic and/or electrically conductive, e.g. an electrically conductive connection), a direct or indirect connection and a direct or indirect coupling. In the figures, identical or similar elements are provided with identical reference signs where this is appropriate.

According to various embodiments, the term “coupled” or “coupling” may be understood in the sense of a (e.g. mechanical, hydrostatic, thermal and/or electrical), e.g. direct or indirect, connection and/or interaction. Several elements can, for example, be coupled together along an interaction chain along which the interaction may be exchanged, e.g. a fluid (then also referred to as fluid-conducting coupled). For example, two coupled elements may exchange an interaction with each other, e.g. a mechanical, hydrostatic, thermal and/or electrical interaction. A coupling of several vacuum components (e.g. valves, pumps, chambers, etc.) with each other may have that these are coupled with each other in a fluid-conducting manner. According to various embodiments, “coupled” may be understood in the sense of a mechanical (e.g. physical) coupling, e.g. by direct physical contact. A coupling may be configured to transmit a mechanical interaction (e.g. force, torque, etc.).

According to various embodiments, a bearing device may be configured for bearing (e.g. guided positioning and/or holding) one or more than one component. For example, the bearing device may have one or more than one bearing, for example per component, for bearing (e.g. guided positioning and/or holding) the component. Each bearing of the loading device may be configured to provide the component with one or more than one degree of freedom (e.g. translational degree of freedom or rotational degree of freedom) according to which the component may be moved. Examples of a bearing include: Radial bearing, axial bearing, radiaxial bearing, linear bearing (also referred to as linear guide). For example, the component may be provided with exactly one degree of translational freedom per linear bearing.

In this context, spatial position may be understood as the spatial information of the orientation and/or location of an object, for example in relation to one or more than one reference (e.g. center of gravity) of the object. The location can, for example, be specified as a coordinate point in space and the orientation as an orientation (e.g. expressed as a direction, solid angle or vector) of the object relative to the space. For example, the location of an object may be specified as the location of the object's center of mass in space. Alternatively or additionally, the orientation may be specified as the relative position (e.g. expressed as a vector or solid angle) of the center of mass and the geometric center of gravity of the object.

A trajectory may be understood as a series of positions along which a movement takes place (e.g. of a laser beam that is directed to the positions). The positions may optionally be linked to a temporal component (i.e. be motion-related, then also referred to as motion), e.g. a timing or speed according to which the motion occurs along the trajectory. In general, the position or other spatial information in three-dimensional space may be described using Cartesian coordinates. However, another coordinate system may also be used, e.g. cylindrical coordinates.

Reference is made here in particular to the terms “pattern” (e.g. process pattern) and “sequence”, which serve to logically group specifications (e.g. expressed in operating parameters) according to which a laser beam is directed onto an object (e.g. a metal plate or a substrate carrier segment). The pattern corresponds to a target power distribution with which the object is to be irradiated and is run through during the irradiation process in which the laser beam is directed onto the object. A sequence may illustratively indicate a temporal sequence (also referred to as order) in which the irradiation takes place. The pattern and the sequence may be expressed together as a trajectory which, when projected onto the object, indicates the spatial power distribution (according to the pattern) and the temporal power distribution (according to the sequence).

Each pattern may comprise or consist of a sequence of parameters (also referred to as irradiation parameters) according to which the irradiation of the object with the laser beam takes place, e.g. a sequence of exactly N (also referred to as number of points) irradiation parameters. In this respect, it may be understood that this grouping of the specifications is exemplary, and that what is described in this respect may of course apply by analogy in any other type of specifications according to which the irradiation of the object takes place.

In this context, an assembly device is understood to be a device that is configured for assembly, for example for assembly on a complementary assembly device (also referred to as a counter-assembly device). Mounting involves the (e.g. rigid) connection of several components to one another by their mounting devices. The assembly may be (for example exclusively) form-fit and/or detachable. The mounting device may preferably have a (e.g. planar) mounting surface which, during mounting, rests against a complementary mounting surface of the counter-mounting device. The mounting device can, for example, have one or more than one (e.g. integral) mounting profile (e.g. form-fitting profile), which is provided, for example, by an unevenness (e.g. protrusion or recess) of the mounting device. Examples of the mounting profile include: a thread, a groove (e.g. to accommodate a feather key and/or dovetail groove), a latching lug, a bayonet catch, a pin, etc. Examples of the unevenness include: an opening (e.g. through hole and/or threaded hole), a bolt (e.g. a threaded bolt)

This is understood to mean a rectangular) extension of a component that is designed to connect it to another component. For example, the tenon may be provided as a stepped end section. The complementary part to the tenon can, for example, have a (e.g. groove-shaped) gap into which the tenon fits (e.g. frictionally and/or sliding against each other). In this case, the tenon may also be referred to as a bung (also known as a bung), especially if it closes a complementary bunghole.

According to various embodiments, the vacuum chamber may be or may be provided by a chamber housing in which one or more chambers may be or may be provided. The chamber housing can, for example, be coupled to a pump arrangement, e.g. a vacuum pump arrangement (e.g. gas-conducting), to provide a negative pressure or a vacuum (vacuum chamber housing) and may be configured in such a stable manner that it may withstand the effect of the air pressure in the pumped-down state. The pump arrangement (comprising at least one vacuum pump, e.g. a high vacuum pump, e.g. a turbomolecular pump) may make it possible to pump a portion of the gas from the interior of the processing chamber, e.g. from the processing chamber. Accordingly, one or more vacuum chambers may be provided in a chamber housing. In other words, the chamber housing may be configured as a vacuum chamber housing or a coating chamber may be configured as a vacuum chamber.

The term “manipulation member” (e.g. including an actuator) may be understood as a transducer that is configured to influence a state, a process (e.g. a coating process) or a device in response to operating (e.g., controlling) the manipulation member. The manipulation member may convert an action supplied to the manipulation member (by which the operation takes place) into mechanical movements or changes in physical variables such as force or movement. For example, a mechanical manipulation member may be configured to convert a force (e.g. torque) supplied to the manipulation member during operation into another force or into a movement. Examples of components of a manipulation member are mechanical and/or include: a valve (e.g. of a pump arrangement and/or gas supply device, a motor (e.g. of a valve or a pump) as electrical actuator, a set screw, a gear or similar.

As used herein, a substrate carrier is understood to be a device which is configured to carry one or more than one substrate. For this purpose, the substrate carrier has a frame (also referred to as a carrier frame), and one or more than one substrate holding device, which may be at least partially (i.e. partially or completely) integrated into the frame and/or at least partially mounted on the frame. Examples of components of the substrate holding device comprise: a recess (also referred to as a substrate pocket) for receiving the substrate; a (e.g. flat) substrate carrier on which the substrate may be placed (e.g. provided in the substrate pocket); a locking mechanism configured to block movement of the substrate relative to the substrate holding device (e.g. positive and/or non-positive locking). The frame may further comprise one or more than one section on which the frame may be supported or mounted. For example, the section may have a mounting device for mounting the substrate carrier.

A coating device is configured to provide a coating material to which, for example, the transport path and/or the substrate are exposed. The coating material can, for example, be emitted towards the transport path and/or the substrate, e.g. in a so-called emission direction. The coating device has, for example, a coating material source by which the coating material is provided (e.g. emitted). The coating device can, for example, be configured to perform a gas phase deposition, e.g. a physical vapor deposition (PVD) or chemical vapor deposition (CVD).

For example, the coating material source may be configured to provide a gaseous coating material (material vapor) and/or liquid coating material, which can, for example, be deposited on the at least one substrate to form a layer. A coating material source may comprise at least one of the following: a sputtering device, a thermal evaporation device (e.g. a laser beam evaporator, an arc evaporator, an electron beam evaporator and/or a thermal evaporator), a precursor gas source, a liquid phase atomizer. A sputtering device may be configured to atomize the coating material by a plasma. A thermal evaporation device may be configured to evaporate the coating material by thermal energy. Depending on the nature of the coating material, sublimation, i.e. thermal conversion of a liquid state (liquid phase) into a gaseous state (gaseous phase), may also occur as an alternative to or in addition to thermal vaporization, i.e. thermal conversion of a solid state (solid phase) into a gaseous state. In other words, the thermal evaporation device may also sublimate the coating material. A liquid phase atomizer may be configured to apply a coating material from the liquid phase, e.g. a dye.

For simplified illustration of the geometry of various components, such as the substrate carrier segment, the substrate carrier and/or holding device, reference is made herein to the pages by way of example.

With respect to various embodiments, reference is made to an axis of symmetry of an object (e.g., a substrate carrier segment), it being understood that not every contour of the object necessarily needs to be symmetrical to the axis of symmetry. For example, the object may have a curved outer surface that is symmetrical about the axis of symmetry. For example, the object may have one or more than one surface (e.g. substrate carrier surface) that is symmetrical to the axis of symmetry. For example, the object may have several recesses that are symmetrical to the axis of symmetry. For example, the object may have two outer edges that are symmetrical to the axis of symmetry. For example, the object may taper symmetrically to the axis of symmetry and/or along the axis of symmetry. Examples of symmetry include: mirror symmetry, translational symmetry, rotational symmetry or combinations thereof.

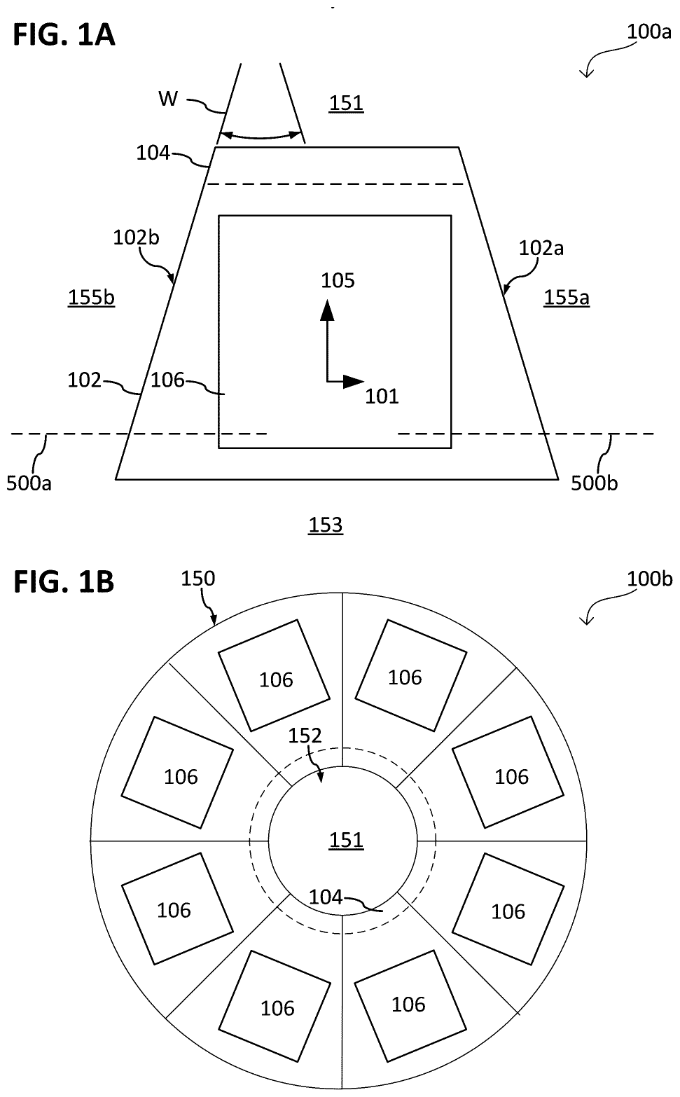

FIG. 1A illustrates a substrate carrier segment according to various embodiments 100a in a schematic side view or cross-sectional view, preferably configured according to Example 1 and/or Example 2, wherein the radial direction 105 and the transport direction 101 are indicated (in the reference system of the substrate carrier segment)

For a simplified illustration of the geometry of the substrate carrier segment, reference is made to its inner side 151 and outer side 153, between which the substrate holding device 106 is arranged, and reference is made to its two end faces 155a, 155b. The radial direction 105 is directed from the outer side 153 towards the inner side 151. The mounting device 104 may face the inner side 151, towards which the support frame 102 tapers.

An exemplary implementation (preferably according to example 40) of the substrate carrier segment has a monolithic plate comprising the support frame 102 and the mounting device 104. Alternatively or additionally (preferably according to Example 38), the mounting device 104 and the support frame 102 are plate-like. It may be understood that the support frame 102 and the mounting device 104 may also be positively joined, for example screwed together.

An exemplary implementation of the substrate holding device 106 has a recess which extends into the plate.

The edges 102a, 102b of the carrier frame 102 facing the end faces 155a, 155b (also referred to as carrier edges 102a, 102b) may run at an angle to one another and/or at an angle to the radial direction 105, e.g. be straight. This achieves that the carrier frame 102 tapers towards the inner side 151. Alternatively or additionally, the mounting device 104 has two opposite edges which continue the carrier edges 102a, 102b.

The edges 102a, 102b of the support frame 102 facing the end faces 155a, 155b may extend at an angle W (also referred to as a side angle) to one another, the bisector of which is along the radial direction 105. The angle may fulfill approximately the following relation: W=360°/k, where the parameter k (also referred to as count k) is a natural number greater than 2, e.g. k≥3, e.g. k≥4, e.g. k≥6, e.g. k≥8, e.g. k≥10. The counter k illustratively indicates the number of substrate carrier segments that form a substrate carrier when joined together, as explained below.

FIG. 1B illustrates a substrate carrier according to various embodiments 100b in a schematic side view or cross-sectional view, which comprises a plurality of substrate carrier segments 150, which are preferably configured according to embodiments 100a. The count rate k is 8 as an example.

The plurality of substrate carrier segments 150 may be joined together (also referred to as the joined state) to form an annular structure in which an opening 152 (also referred to as the carrier opening 152) of the substrate carrier is formed. The mounting device 104 of each substrate carrier segment 150 may be adjacent to the carrier opening 152.

The carrier opening 152 illustratively provides installation space for a substrate carrier holding device, which for example has a hub. The carrier edges of directly adjacent substrate carrier segments 150 may interlock when joined together, as will be explained in more detail later.

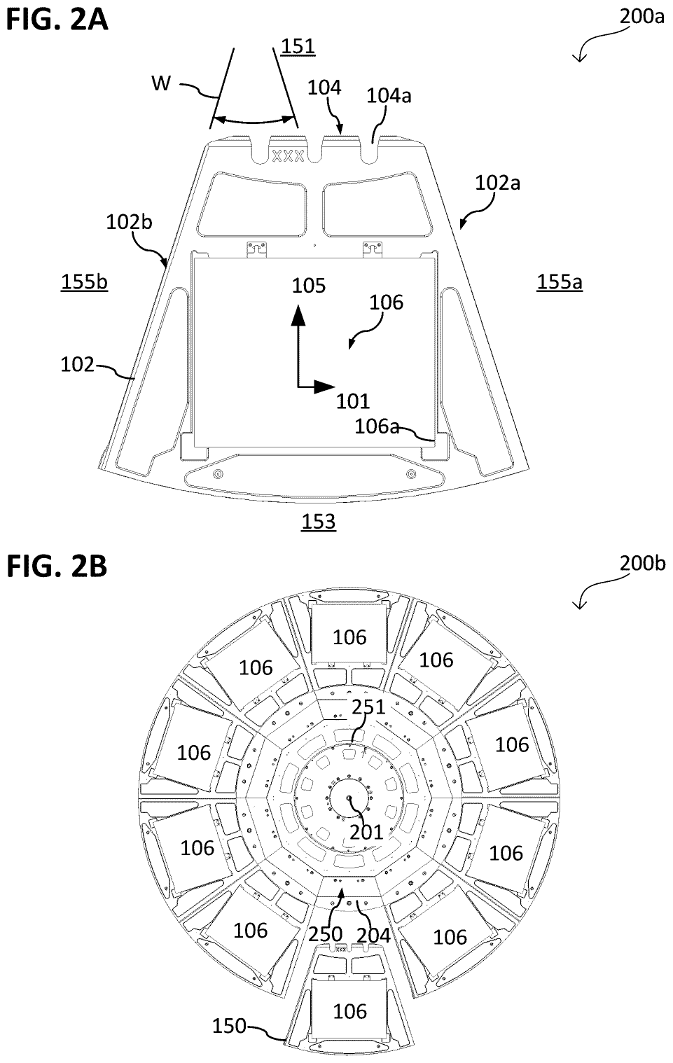

FIG. 2A illustrates a substrate carrier segment according to various embodiments 200a in a schematic side view or cross-sectional view, preferably configured according to one of embodiments 100a to 100b.

An exemplary implementation of the mounting device 104 has one or more than one positive locking contours to facilitate mounting. An exemplary implementation a positive locking contour (preferably according to example 39) is provided by a mounting recess, which is open in the radial direction 105. Each mounting recess 104a can, for example, taper in the radial direction 105. This facilitates assembly.

An exemplary implementation (preferably according to) of the substrate holding device 106 has a support surface 106a (also referred to as a substrate carrier), which delimits the recess. For example, the support surface 106a may be provided by a protrusion.

FIG. 2B illustrates a transport device comprising a substrate carrier holding device 250 and a substrate carrier (preferably configured according to example 18), according to various embodiments 200b in a schematic side view or cross-sectional view, preferably configured according to one of embodiments 100a to 200a. The count rate k is 10, by way of example

In the reference system of the substrate carrier, the radial direction 105 of each substrate carrier segment is directed towards the axis of rotation 201 and/or perpendicular to the axis of rotation 201. In operation, the substrate carrier may be rotated about the axis of rotation 201 so that each substrate carrier segment is transported along a circular transport path. The transport direction 101 of each substrate carrier segment may be tangential to the transport path and/or perpendicular to the axis of rotation 201.

The substrate carrier holding device 250 has a number of k mounting sockets 204, for example one mounting socket 204 per substrate carrier segment 150. The mounting socket 204 is configured to establish a connection with the mounting device 104 in order to mount the substrate carrier segment 150 to the substrate carrier holding device 250.

An exemplary implementation of the substrate carrier holding device 250 (preferably according to example 19) further includes a bearing device 251 (also referred to as a hub), by which the mounting socket 204 is rotatably supported about a rotational axis 201 of the bearing device. For this purpose, the bearing device may comprise one or more than one pivot bearing by which the pivot axis 201 is provided.

Mounting a substrate carrier segment 150 may comprise moving the substrate carrier segment 150 in the radial direction to the substrate carrier holding device 250 so that the mounting device 104 and the mounting sockets 204 contact each other, for example interlocking.

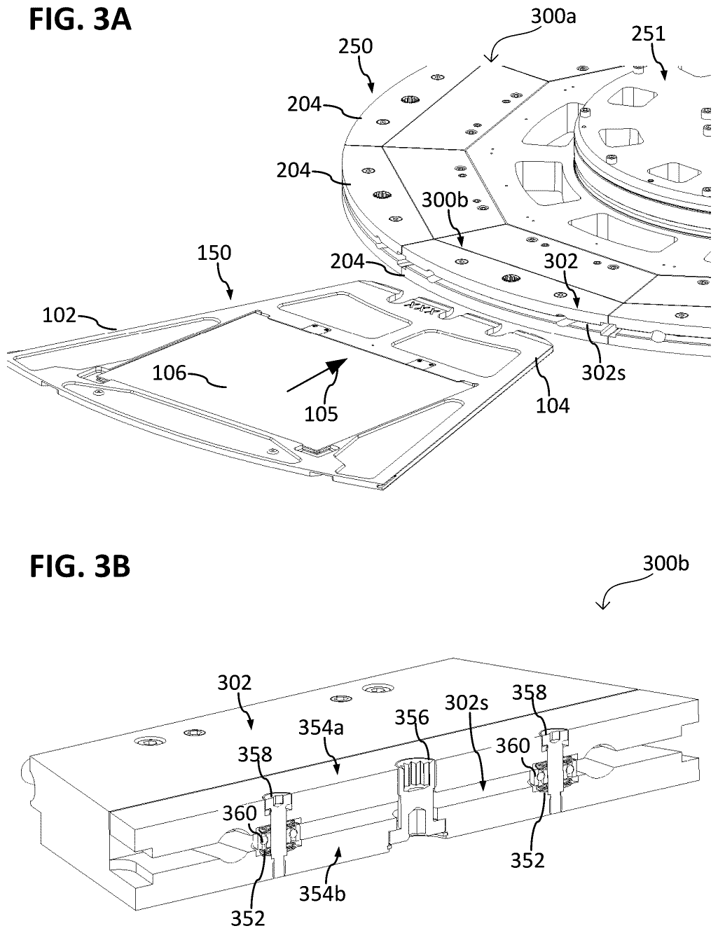

FIG. 3A illustrates a transport device comprising a substrate carrier holding device 250 and a substrate carrier (preferably configured according to example 18) according to various embodiments 300a in a schematic perspective view, preferably configured according to one of embodiments 100a to 200b.

An exemplary implementation of the mounting socket 204 (preferably configured according to Example 21) has a receiving device 302 for receiving a substrate carrier segment 150, which provides a receiving gap 302s. The receiving gap 302s is configured to receive the mounting device 104, for example such that the mounting device 104 may be inserted into the receiving gap 302s.

FIG. 3B illustrates a receiving device (preferably configured according to example 22), according to various embodiments in a schematic cross-sectional view 300b, preferably configured according to one of embodiments 100a to 300a

An exemplary implementation (preferably according to Example 23) of the receiving device 302 has one or more than one spring 352, which is arranged in the receiving gap 302s between the two clamping jaws 354a, 354b (e.g., chuck jaws). The spring 352 is configured to impart a first force (also referred to as restoring force) between the clamping jaws, against which the clamping jaws 354a, 354b may be moved towards each other. Furthermore, the mounting socket 204 has one or more than one screw as a manipulation member 356 (also referred to as a mounting member). The mounting member 356 is configured to influence a distance between the two clamping jaws 354a, 354b, for example by turning the screw (then also referred to as clamping screw). The mounting member 356 can, for example, be configured to engage in a mounting recess 104a of the mounting device 104. This facilitates assembly.

The or an alternative exemplary implementation (preferably according to example 23) of the receiving device 302 has one or more than one positive locking contour (also referred to as a base contour) as a guide member, which is extended into the receiving gap 302s and/or is configured to engage with the mounting device 104. An exemplary implementation (preferably according to) of the guide member is implemented, for example, by a protrusion 358 (also referred to as a guide member) which extends into the receiving gap 302s. For example, the receiving device 302 may have two guide members 358, between which, for example, the mounting member 356 is arranged.

Each guide member 358 may, for example, be configured to engage in a mounting recess 104a of the mounting device 104. This facilitates assembly. For example, each of the guide members 358 may extend through one of the springs and/or be implemented by a screw.

An exemplary implementation (preferably according to example 24) of the guide member 358 has a ball bearing 360, which provides a rotatably mounted ring. This facilitates assembly. For example, the mounting device may have two springs per guide member, between which the ball bearing 360 is arranged, so that the restoring force is imparted by the ball bearing 360. This simplifies the design, as fewer parts are required to hold the ball bearing 360 and generate the restoring force.

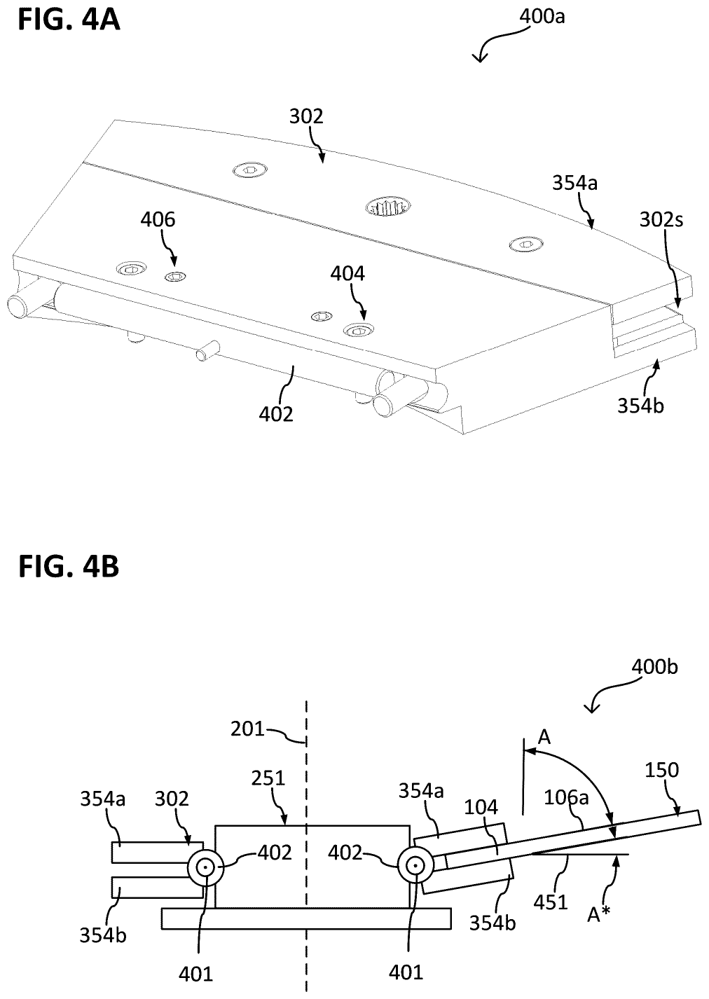

FIG. 4A illustrates a mounting socket (preferably configured according to example 20) according to various embodiments 400a in a schematic perspective view, preferably configured according to one of embodiments 100a to 300b. The bearing device 402 of the mounting socket (also referred to as base bearing 402) illustratively provides a pivot joint (e.g., including one or more than one hinge) that movably connects the mounting device 302 to the hub 251

An exemplary implementation of the pedestal bearing 402 provides an axis of rotation (also referred to as an alignment axis), which is arranged at a distance from the receiving device 302 or at least from the receiving gap 302s. This achieves that the alignment of the receiving device 302 or at least of the receiving gap 302s may be changed.

An exemplary implementation of the first manipulation member 404 (also referred to as an alignment member) has one or more than one screw (also referred to as an alignment screw), which is, for example, screwed into the receiving device 302. The alignment screw is configured to change the alignment of the holding device 302 relative to a plane (also referred to as the reference plane) which is transverse to the axis of rotation 201, for example by rotating the alignment screw. This changes the angle between the axis of rotation 201 and the holding device 302.

For example, the alignment screw may be configured to impart a force between the receiving device 302 and the hub 251. For this purpose, the alignment screw may, for example, extend through the receiving device 302 and press with its end portion against a support device of the hub 251 when the receiving device 302 is rotated into it.

An exemplary implementation of the locking device 406 has one or more than one screw (also referred to as a locking screw), which is configured to block the rotational degree of freedom of the holding device 302, which is provided by the base bearing 402, for example by screwing the locking screw in, or to release it, for example by screwing the locking screw out. This makes it easier to precisely align the substrate carrier segments and to lock them in place

Alternatively or additionally, the locking device 406 may be configured to limit an angle through which the receiving device 302 may be moved to a range (also referred to as a pivot range) which is a function of a state of the locking device 406. Preferably, the locking device 406 may be configured to reduce the pivot range when brought into a first state, for example by turning the locking screw). Preferably, the locking device 406 may be configured to increase the swivel range when it is brought into a second state, for example by turning the locking screw).

FIG. 4B illustrates a transport device comprising a substrate carrier holding device 250 and a substrate carrier (preferably configured according to example 18), according to various embodiments 400b in a schematic side view or cross-sectional view, preferably configured according to one of embodiments 100a to 400a. The alignment axis 401 of each mounting socket 204s may be transverse to the axis of rotation 201 of the hub 251 and/or parallel to the reference plane 451.

The reference plane 451 may illustratively serve as a reference plane for the alignment of the substrate carrier surface and/or for the alignment angle A. For example, the alignment angle A. may be approximately 90° during operation. The alternating angle A* of the alignment angle A may, for example, be included between the reference plane 451 and the substrate carrier surface.

Illustratively, the substrate carrier segment, when mounted by its mounting device 104 (also referred to as the mounted state), may be understood as a cantilever beam which deforms due to the gravitational force acting thereon, for example according to a bending line. The position of the substrate carrier segment in the mounted state relative to the reference plane may be, among other things, a function of the deformation and/or various parameters (e.g. properties of the substrate carrier segment and/or the mounting socket), which may differ from one another for several substrate carrier segments.

Examples of these parameters (also referred to as position parameters), which may differ from each other for several substrate carrier segments of the substrate carrier (also referred to as position parameter variance), include: a curvature in the unloaded state, a mechanical stiffness, a position in the mounted state with respect to the mounting socket, a (e.g. thermal and/or mechanical) stress in the mounted state, a history, a crystal structure of the substrate carrier segment, etc. Some of the properties of a substrate carrier segment may be time-dependent and may change over time (e.g. due to thermal stress). Likewise, tolerances (of manufacture and/or assembly) may cause these position parameters to differ from one another. This applies analogously to the mounting sockets themselves.

The position parameter variance has the consequence that, for example, despite precise manufacturing of the mounting sockets and the substrate carrier segments and mounting of these to one another, several substrate carrier segments of the substrate carrier differ from one another in their position (e.g. the position of the substrate carrier surface 106a) relative to the reference plane (also referred to as position difference). This position difference may be reduced, for example, by changing the alignment angle A. For this purpose, the alignment member may be actuated and/or the alignment angle A may be changed in accordance with a specification which represents a target position of the substrate carrier segment.

Similarly, the support contours, if present, may help to reduce the difference in position. Various implementations of the support contours are explained below.

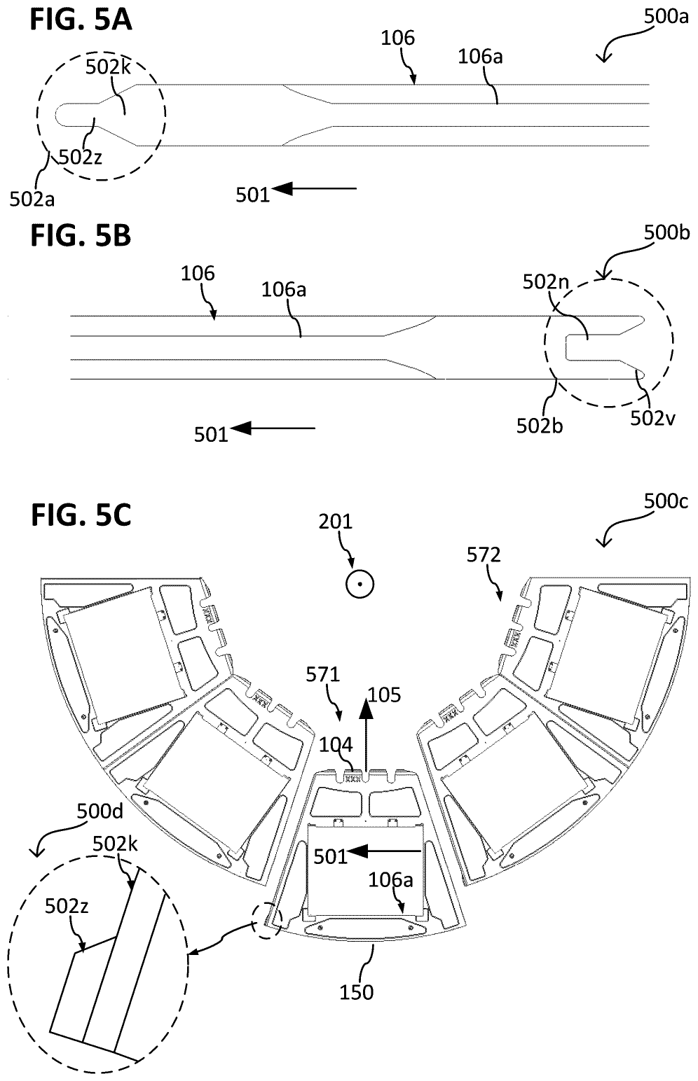

FIGS. 5A and 5B each illustrate a substrate carrier segment (preferably configured according to Example 1 and/or Example 2) according to various embodiments in a schematic cross-sectional view 500a and 500b looking in the radial direction 105, preferably configured according to one of the embodiments 100a to 400b. Furthermore, a direction 501 (also referred to as insertion direction 501 for illustration purposes) is shown, which is, for example, the transport direction 101 or antiparallel to the transport direction 101.

The two support edges 102a, 102b, e.g. their first support edge 102a, may have a first support contour 502a. The two support edges 102a, 102b, e.g. their second support edge 102b, may have a second support contour 502b, which is arranged complementary to the first support contour 502a. The first supporting contour 502a and the second supporting contour 502b may, for example, be configured to interlock (also referred to as contour interlocking) and/or may lie opposite one another. The support contours enable two directly opposite substrate carrier segments of the substrate carrier to interlock with their support contours, thereby aligning with each other (also referred to as centering) and supporting each other.

This inhibits the difference in position.

An exemplary implementation of the first support contour 502a (preferably according to Example 11) is implemented by a (e.g. stepped) protrusion, which protrudes, for example, in the insertion direction 501 away from the substrate holding device 106. The protrusion may, for example, have a wedge-shaped section 502k and/or taper at least sectionally in the insertion direction 501, which improves centering. Alternatively or additionally, the protrusion may have a peg-shaped section 502z (also referred to as peg 502z), which for example provides a bung and/or continues the wedge-shaped section 502k (also referred to as centering wedge 502k), for example protruding therefrom in the insertion direction 501.

An exemplary implementation of the second support contour 502b is implemented by a (e.g., stepped) depression that is open in a direction away from the substrate holding device 106 (from the mating direction 501). The recess may, for example, have a funnel-shaped section 502v (also referred to as a centering funnel) and/or taper at least sectionally towards the substrate holding device 106 (and/or away from the insertion direction 501), which improves centering. Alternatively or additionally, the recess may have a groove-shaped section 502n (also referred to as groove 502n), which for example provides a bung hole and/or continues the tapering section 502v, e.g. in the insertion direction 501. The first support contour 502a and the second support contour 502b can, for example, be configured to be inserted one into the other. When mating, for example, the pin 502z may be inserted into the centering funnel 502v, e.g. sliding against its inner wall, and then inserted into the groove 502n, e.g. sliding against its inner wall.

An exemplary implementation of the pin 502z and/or the groove 502n are configured in such a way that they have less than 10^{-g}cm (centimeters) play relative to each other (e.g. transverse to the mating direction 501) when mated, where g≥0, e.g. g≥1, e.g. g≥2.

An exemplary implementation of the centering wedge 502k and/or the centering funnel 502v are configured in such a way that they have less than 10^{-g}cm (centimeters) play relative to each other (e.g. transverse to the insertion direction 501) when inserted into each other, where g≥0, e.g. g≥1, e.g. g≥2.

FIG. 5C illustrates a substrate carrier (preferably configured according to example 18) according to various embodiments in a schematic plan view 500c looking along the axis of rotation 201, preferably configured according to one of embodiments 100a to 500b, and a detailed view 500d thereof.

An exemplary implementation of a method for forming the substrate carrier comprises transporting (also referred to as segment insertion) a substrate carrier segment 150 into an area 571 (also referred to as segment area) formed between two immediately adjacent substrate carrier segments of a group 572 of substrate carrier segments (also referred to as segment group 572), e.g. towards the axis of rotation 201, e.g. along its radial direction 105, which is directed towards the axis of rotation 201. During segment insertion, mating may be accomplished, for example, by inserting the first positive locking contour 502a of the substrate carrier segment 150 into a second positive locking contour 502b of the segment group 572 adjacent to the segment region. For example, the peg 502z of the substrate carrier segment 150 may be inserted into a centering funnel 502v of the segment group 572 adjacent to the segment region, e.g. sliding against its inner wall, and then inserted into a groove 502n of the segment group 572 continuing the centering funnel 502v, e.g. sliding against its inner wall. During insertion, the substrate carrier segment 150 may be aligned with the segment group 572 (also referred to as centering).

During segment insertion, for example, the mounting device 104 may further be received by the receiving device (not shown) of the substrate carrier holding device, for example by the receiving gap.

The method may further comprise mounting (also referred to as mounting the substrate carrier segment) and/or aligning (also referred to as aligning the substrate carrier segment) the substrate carrier segment 150 to the substrate carrier holding device (e.g., the mounting socket thereof) by its mounting device 104.

An exemplary implementation of aligning the substrate carrier segment 150 features actuating the first manipulation member such that an angle between the substrate carrier surface 106a of the substrate carrier segment 150 and the rotation axis 201 is changed. The alignment of the substrate carrier segment 150 may optionally comprise actuating the locking device, so that a change in the angle between the substrate carrier surface 106a of the substrate carrier segment 150 and the axis of rotation 201 is blocked.

An exemplary implementation of the mounting of the substrate carrier segment comprises actuating the second manipulation member so that the mounting device 104 is positively and/or non-positively connected to the mounting socket (not shown). As explained herein, the second manipulation member may, for example, be configured to transmit a force to the clamping jaws, which triggers a movement of the clamping jaws towards each other and/or clamps the mounting device 104 by the clamping jaws.

It may be understood that the method may alternatively or additionally proceed in reverse order to remove a substrate carrier segment from the substrate carrier.

It may be understood that the method may generally comprise segment swapping. For example, the segment swapping may comprise exchanging a first substrate carrier segment of the substrate carrier for a second substrate carrier segment. Alternatively, the segment swapping may comprise disassembling the first substrate carrier segment of the substrate carrier, exchanging the substrate disposed therein for another substrate, and reassembling the first substrate carrier segment.

Segment swapping can, for example, be performed by a transport device (also referred to as a segment transport device or handler), e.g. an end effector of the segment transport device. For example, the end effector may be coupled to the substrate carrier segment before the substrate carrier segment is removed from the substrate carrier.

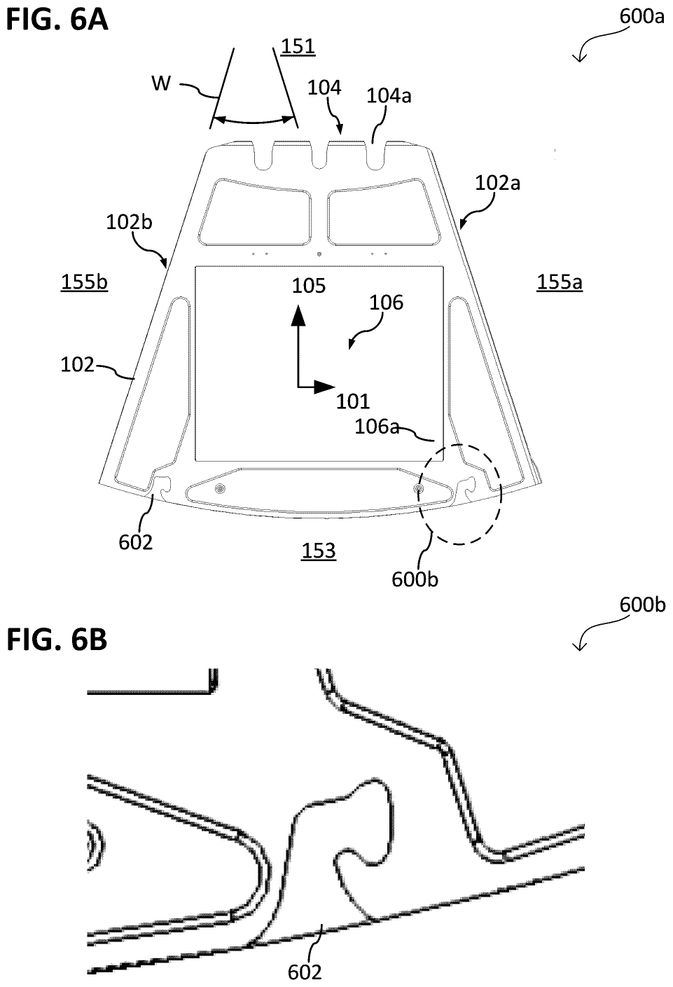

FIG. 6A illustrates a substrate carrier segment according to various embodiments 600a (preferably according to example 17) in a schematic side view, preferably configured according to one of embodiments 100a to 500c; and FIG. 6B a detailed view 600b thereof.

An exemplary implementation of the outer side 153 of the substrate carrier segment has two coupling recesses 602, by which a coupling device is implemented. The coupling recesses 602 may be configured to receive an end effector that engages in the coupling recesses 602. By the end effector, the substrate carrier segment may be removed from or added to a substrate carrier, for example when exchanging segments.

An exemplary implementation of the end effector has, for example per coupling recess of the substrate carrier segment, a complementary coupling device, for example in the form of a coupling shoe, with which the end effector engages in the coupling recess.

An exemplary implementation (preferably according to) the or each coupling recess 602 is angled (e.g., in the transport direction 102 or opposite the transport direction 102). This facilitates locking a (e.g., positive) connection of the end effector engaging the recesses 602 to the substrate carrier segment. For example, several coupling recesses may match in the direction in which they are angled, which makes it possible to trigger the locking by a rotary movement of the substrate carrier holding device.

The angled clutch recess 602 can, for example, be provided in the form of a meandering passage which is thickened at its dead end. This simplifies locking even further.

An exemplary implementation (preferably according to) the or each coupling recess 602 has a portion that tapers towards the mounting device, adjacent the outer surface 153. This facilitates insertion of the end effector into the coupling recess 602.

An exemplary implementation (preferably according to) the or each coupling recess 602 has a meandering passageway, tapering towards the mounting device, adjacent the outer surface 153. This facilitates insertion of the end effector into the coupling recess 602.

As explained with respect to the position parameters, the manufacture of the substrate carrier segment may have an influence on some position parameters, including for example the curvature in the unloaded state and/or the mechanical stiffness of the substrate carrier segment. According to various embodiments, aspects of the manufacture of the substrate carrier segment are provided which reduce the position parameter variance, which is explained in more detail below.

According to various embodiments, the fabrication of a substrate carrier segment may be carried out by a thermal process, e.g. a thermal ablation process. For this purpose, reference is made to an exemplary thermal process which is carried out by a laser (e.g. laser ablation process), whereby what is described for this may apply by analogy to any other thermal process. The thermal process may be carried out according to a process pattern, for which various examples are explained below.

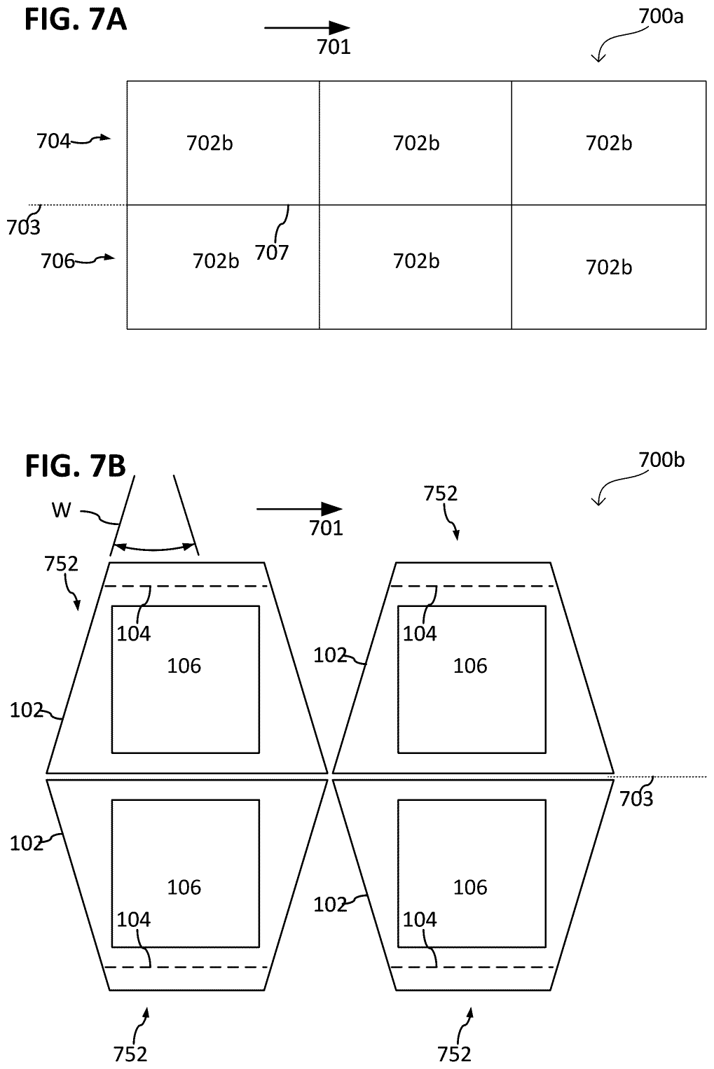

FIG. 7A illustrates a process pattern of the first type according to various embodiments 700a (for example according to example 33) in a schematic diagram, according to which the manufacturing of a plurality of substrate carrier segments preferably configured according to embodiments 100a to 600b takes place.

An exemplary implementation of the first type process pattern (also referred to as a layer pattern) has one or more than one row 704, 706 arranged in series along a direction 701 (also referred to as a row direction 701) of irradiation regions 702b (in which case also referred to as ablation regions 702b), each ablation region 702b of which is used to form a substrate carrier segment therefrom. For example, the layer pattern may include a plurality of rows 704, 706 (also referred to as a multi-row pattern) arranged side-by-side. For example, each row may have a number R of ablation regions 702b disposed one behind the other, where R is greater than 1, e.g. k≥3, e.g. k≥4, e.g. k≥6, e.g. k≥8, e.g. k≥10.

An exemplary implementation of the row direction 701 (preferably according to Example 16) is parallel to a direction (also referred to as rolling direction) in which a metal plate from which the substrate carrier segments are produced is rolled. This takes into account that the crystal structure of rolled metal is anisotropic and may have a preferred direction along the rolling direction. This further takes into account that a stiffness and/or deformation of the substrate carrier segment may be anisotropic in the same way. For example, the metal plate may be hot rolled. This applies by analogy to the edges (also referred to as the rolled edge) of the metal plate, towards which the crystal structure may change.

An exemplary implementation of the multi-row pattern has exactly two rows that are adjacent to one another at an axis 703 and/or are arranged symmetrically to the axis 703, the axis 703 is preferably along the row direction 701, the rolling direction and/or the rolling edge. For example, the ablation areas 702b may be arranged and aligned symmetrically to the axis 703.

An exemplary implementation of each ablation region 702 has a (e.g., digital) representation (also referred to as a geometry representation) of the substrate carrier segment to be produced, e.g., the geometry of the substrate carrier segment to be produced and/or one or more than one contour of the substrate carrier segment to be produced. The layer pattern may thus have one geometry representation per ablation area 702. The geometry barrier representation can, for example, be specified as a trajectory along which the laser beam is guided.

An exemplary implementation of the geometry barrier representation is aligned symmetrically to the row direction 701, the axis 703, the rolling direction and/or the rolling edge. In the case of the multi-row pattern, the geometry barrier representations may be aligned symmetrically to the axis 703.

An exemplary implementation of the laser ablation process comprises irradiating the metal plate according to the position pattern by the laser, e.g. according to each geometry representation of the position pattern. Here, each of the ablation regions 702 may be divided by the laser (then also referred to as a laser dividing process) into a plurality of parts, one part of which is configured according to the geometry representation and is processed into a substrate carrier segment.

FIG. 7B illustrates a layer pattern according to various embodiments 700b in a schematic diagram, according to which the manufacturing of several substrate carrier segments is carried out, which are preferably configured according to embodiments, wherein for simplified understanding each of the geometry representations 752 is provided with the reference signs of the substrate carrier segments to be manufactured

An exemplary implementation of the multi-row pattern has several pairs of ablation regions 702b, which are disposed one behind the other along the row direction and/or of which each pair has two geometry barrier representations, which are arranged symmetrically to the axis 703 (then also referred to as the symmetry axis) of the position pattern. For example, the geometry barrier representations may face each other with their outer side 153.

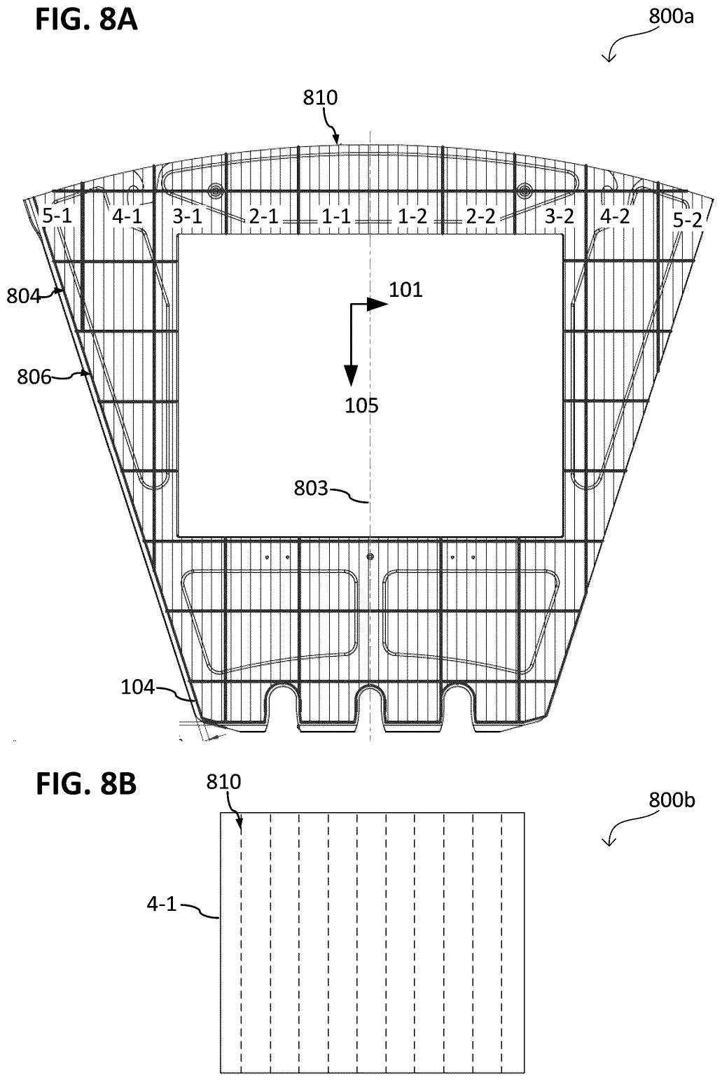

FIG. 8A illustrates a second type process pattern according to various embodiments 800a (for example according to Example 33) in a schematic diagram, according to which manufacturing of a plurality of substrate carrier segments preferably configured according to embodiments 100a to 700b; and FIG. 8B a detailed view 800b of a modification area.

An exemplary implementation of a method based on the process pattern of the second type (also referred to as modification pattern) comprises irradiating a result of the laser splitting process (e.g. the substrate carrier segment in a preliminary stage thereof) by the laser according to the modification pattern. The irradiation by the laser according to the modification pattern may be configured to change the surface of the result of the laser dividing process, e.g. to increase its roughness (then also referred to as roughening) and/or adhesion promotion. Roughening illustratively favors the adhesion of a coating to the substrate carrier segment, which reduces the frequency of cleaning the substrate carrier segment.

An exemplary implementation of the roughness laser is configured to increase the roughness, for example by a factor of 10^{r}, where r≥0, e.g. r≥1, e.g. r≥2.

An exemplary implementation of the modification pattern implements a temporal sequence (also referred to as a modification sequence) and/or has a plurality of pairs of irradiation regions (in which case also referred to as modification regions), which are indexed herein by a tuple (x-y), where x references the pair and y references the order in which the two modification regions of the pair are irradiated. For example, the modification pattern may comprise one or more than one row 804, 806 of modification regions arranged in series along the transport direction 101 (then also referred to as row direction 101), each row comprising a plurality of pairs of modification regions. Each row may, for example, have a number of R modification areas arranged in series, where R is greater than 1, e.g. k≥3, e.g. k≥4, e.g. k≥6, e.g. k≥8, e.g. k≥10.

An exemplary implementation of each pair x of modification areas has two modification areas x-1 and x-2, which are symmetrically arranged (e.g. arranged) with respect to an axis 803. This axis 803 can, for example, be parallel to the radial direction 105, transverse to the transport direction 101 and/or be the bisector of the side angle W.

An exemplary implementation of the modification sequence has one or more than one temporal order according to which the irradiation takes place, e.g. a first and a second temporal order. The first time sequence is related to the index x and causes the pairs to be processed one after the other according to their index x. The first temporal sequence is, for each pair of modification areas, related to the index y of the pair and causes the modification areas of the pair to be processed one after the other according to their indices y. For example, the modification areas are processed one after the other in the following order: 1-1, 1-2, 2-1, 2-2, 3-1, 3-2, 4-1, 4-2, 5-1, 5-2, etc. This ensures that the substrate carrier segment is processed as symmetrically as possible.

An exemplary implementation of each modification area (see also detailed view 800b) implements one or more than one trajectory 810 along which the irradiation takes place. The trajectory 810 may, for example, have several sections running side by side and/or linearly, or at least several rows of irradiation positions disposed one behind the other, to which the laser beam is directed

An exemplary implementation of the trajectory 810 has one or more than one section that runs linearly along the axis 803 and/or the radial direction 105. This improves the symmetry of the machining and thus reduces the deformation.

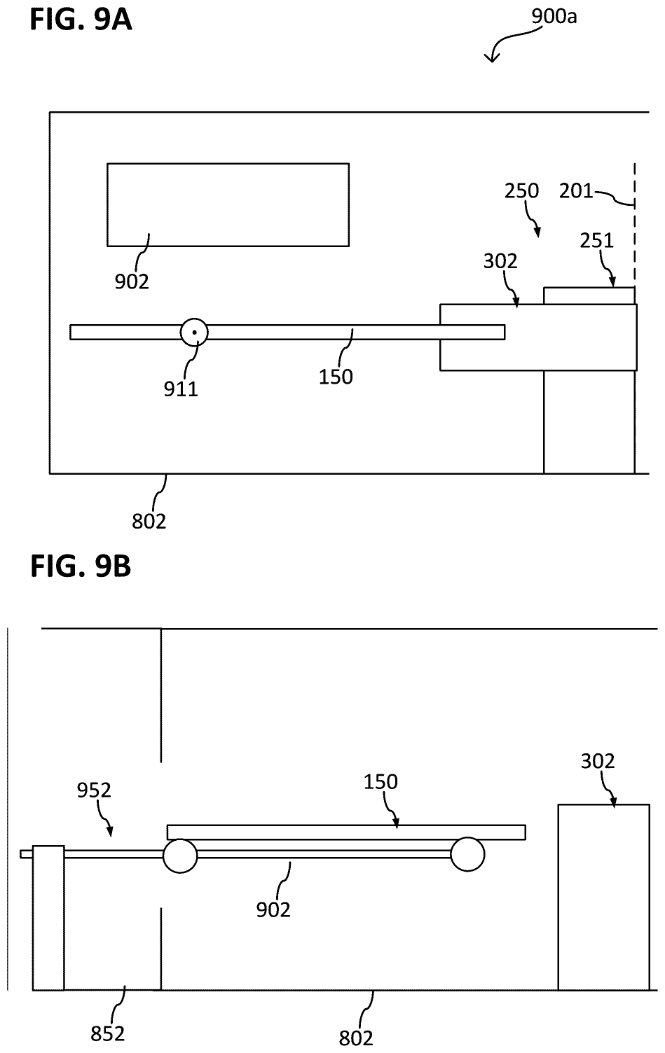

FIG. 9A illustrates a vacuum arrangement according to various embodiments 900a (for example according to example 27) in a schematic cross-sectional view, in which the substrate carrier holding device and the substrate carrier are arranged, which are preferably configured according to embodiments 100a to 800b. An exemplary implementation of the vacuum arrangement (preferably according to Example 28) comprises one or more than one coating device 902 in the vacuum chamber 802, which is configured to emit a coating material, to the transport path 911 along which the substrate carrier segments 150 of the substrate carrier are transported.

FIG. 9B illustrates a vacuum arrangement according to various embodiments 900b (for example according to example 27) in a schematic cross-sectional view, in which the substrate carrier holding device and the substrate carrier are arranged, which are preferably configured according to embodiments 100a to 900a. An exemplary implementation of the vacuum arrangement comprises a segment transport device 952, which is configured to transport a substrate carrier segment 150 towards or away from the substrate carrier holding device 250. For example, segment swapping may be performed by the segment transport device 952. The segment transport device 952 can, for example, be arranged in an additional vacuum chamber 852, which is arranged next to the vacuum chamber 802.

Various examples of work are described below, which relate to what is described above and shown in the figures.

An exemplary working example 1 has a vacuum arrangement that is configured as a turntable coating system.

An exemplary working example 2 provides a multi-part turntable comprising a set of several circular ring segment-shaped substrate carrier segments (for example in the form of cake pieces). Furthermore, a hub is provided for holding the substrate carrier segments.

An exemplary working example 3 increases the precision with regard to the position of the substrate carrier relative to the coating source and/or reduces costs and effort.

An exemplary working example 4 facilitates the assembly of each substrate carrier segment. The substrate carrier holding device has a hub and, attached to it, a clamping jaw (e.g., chuck jaw) per substrate carrier segment for mounting and aligning the substrate carrier segment. The clamping jaw may be rotatably mounted, for example by a pivot joint (e.g., including one or more than one hinge) with a shaft. The pivot joint makes it easier to tilt and/or lift the substrate carrier, or more generally speaking, to align it. Furthermore, additional screws may be provided to lock the resulting position of the pivot joint.

An exemplary working example 5 has two clamping jaws (e.g., chuck jaws), between which the substrate carrier segment is guided by ball bearings. Furthermore, there are several springs between the clamping jaws, which push the clamping jaws apart. The substrate carrier segment, e.g. its mounting device, has recesses complementary to the ball bearings, into which ball bearings and/or a clamping screw engage.

An exemplary working example 6 provides that the clamping jaws and the substrate carrier segment interlock vertically, which inhibits the movement of the substrate carrier segment relative to the clamping jaws and favors centering. For example, these may interlock positively. Round contours make it easier to correct a potential misalignment.

An exemplary working example 7 provides an improved geometry of the substrate carrier segment, which has an angled elongated hole as a coupling receptacle into which the handler may engage. By turning the turntable, a positive coupling between the substrate carrier segment and the handler may be created or released. Two slotted holes per substrate carrier segment may each be angled in the same direction.

An exemplary working example 8 provides a groove-pin connection between directly adjacent substrate carrier segments of the substrate carrier. A wedge-shaped projection facilitates the centering of the directly adjacent substrate carrier segments. An additional peg (e.g. a lug) on the wedge-shaped projection, disposed on the outer circumference of the substrate carrier, makes it possible to level the substrate carrier segment by engaging the projection in the recess. The tongue and groove connection can, for example, only create an external connection so that the position of the substrate carrier segment may be varied more easily by the first manipulation member.

An exemplary working example 9 provides symmetrical processing of the substrate carrier segment, which inhibits subsequent deformation of the carrier due to mechanical stress.

An exemplary working example 10 provides a substrate holding device that may hold several substrates, e.g. a stack of several substrates. For this purpose, the substrate holding device can, for example, have a (e.g. frame-shaped) spacer (also referred to as spacer), which is arranged between two substrates of the stack.

An exemplary working example 11 provides a plurality of substrate carriers, each substrate carrier comprising a plurality of substrate carrier segments which, when joined together, form the substrate carrier, and of which at least two substrate carriers differ from one another, for example in a geometry of the substrate carrier segments and/or the substrate holding device (e.g. size, shape, type).

An exemplary working example 12 provides an improved production of the substrate carrier segment. For this purpose, the substrate carrier segment may be roughened by roughening lasering, whereby the roughening lasering is carried out according to a pattern (e.g. of processing areas) which are symmetrical to a nominal curvature of the carrier that remains after roughening lasering. Alternatively or additionally, several substrate carrier segments may be laser-cut from sheet, the edge areas of which remain (showing the rolled edge). The edge areas have a different structure to the rest of the sheet. The laser cutting may be carried out symmetrically to the rolling direction.

An exemplary working example 13 provides an axis of symmetry to which the process pattern is symmetrical, wherein the axis of symmetry passes through a center of gravity, e.g. center of mass and/or geometric center of gravity.

An exemplary working example 14 provides an axis of symmetry of the substrate carrier surface to which the process pattern is symmetrical.

1. A substrate carrier segment comprising:
a support frame;
a substrate holding device for holding a substrate and being at least partially integrated into the carrier frame or mounted thereon;
a mounting device adjacent to the carrier frame, towards which the carrier frame tapers, for mounting the substrate carrier segment; and
two complementary form-fitting contours, between which an outer side of the carrier frame, which is opposite the mounting device.

2. The substrate carrier segment according to claim 1, wherein the substrate holding device is arranged between the outer side and the mounting device.

3. The substrate carrier segment according to claim 1, wherein the two form-fit contours are configured for centering by interlocking.

4. The substrate carrier segment according to claim 1, wherein one of the form-fit contours is wedge-shaped at least sectionally.

5. The substrate carrier segment according to claim 4, wherein the form-fit contour comprises a peg-shaped plug-in device.

6. The substrate carrier segment according to claim 1, further comprising:
an axis of symmetry to which a processing pattern, according to which the substrate carrier segment is roughened, is symmetrical and to which a rolling direction of the substrate carrier segment extends transversely.

7. The substrate carrier segment according to claim 1, further comprising:
an angled recess on the outside, which extends towards the mounting device.

8. A substrate carrier holding device comprising:
an axis of rotation;
a plurality of mounting sockets arranged in a pattern around the axis of rotation;
a receiving device for receiving a substrate carrier segment;
a pivot joint, by which the receiving device is movably mounted; and
a first manipulation member configured to change an angle between the axis of rotation and the receiving device.

9. The substrate carrier holding device according to claim 8, further comprising two clamping jaws movably mounted relative to one another and between which a receiving gap is formed.

10. The substrate carrier holding device to claim 9, wherein the mounting socket comprises a second manipulation member for transmitting a force to the clamping jaws.

11. A method for forming a substrate carrier segment comprising:
carrying out a thermal irradiation process according to a process pattern that is symmetrical to an axis of symmetry of the substrate carrier segment.

12. The method according to claim 11, wherein the thermal irradiation process is carried out by a laser.

13. The method according to claim 11, wherein the process pattern implements several pairs of irradiation areas, wherein the irradiation areas of a pair are exposed to the irradiation process symmetrically to the axis of symmetry and immediately one after another.

14. The method according to claim 11, wherein the process pattern is symmetrical:
to a rolling direction of the substrate carrier segment or at least one pre-product from which the substrate carrier segment is formed; and/or
to a rolled edge of the substrate carrier segment or at least of the pre-product.

15. The method according to claim 11, further comprising:
controlling the thermal irradiation process according to the process pattern; and
forming the substrate carrier segment by the irradiation process.

16. The substrate carrier segment according to claim 1, wherein the two complementary form-fitting contours are configured for gapless interlocking.

17. The substrate carrier segment according to claim 1, wherein the two complementary form-fitting contours are configured to transfer a force between each other when interlocked.

18. The substrate carrier segment according to claim 1, wherein the two complementary form-fitting contours are configured for transition-fitting into each other.

19. The substrate carrier segment according to claim 18, wherein the two complementary form-fitting contours are configured for sliding-fitting into each other.

20. The substrate carrier segment according to claim 1, wherein the two complementary form-fitting contours, when interlocking each other, provide a 90% space fill.
